(19) United States
(12) Patent Application Publication
(10) Pub. No.: US 2026/0123217 A1
(43) Pub. Date: Apr. 30, 2026

(54) DISPLAY DEVICE AND ELECTRONIC DEVICE HAVING THE SAME

(71) Applicant: Samsung Display Co., LTD., Yongin-si (KR)

(72) Inventor: Jin Uk HWANG, Yongin-si (KR)

(21) Appl. No.: 19/368,044

(22) Filed: Oct. 24, 2025

(30) Foreign Application Priority Data
Oct. 24, 2024 (KR) 10-2024-0146919

(51) Int. Cl. H10K 59/131; H05K 1/18; H10K 59/12; H10K 59/121; H10K 59/80; H10K 59/88

(52) U.S. Cl. CPC H10K 59/131; H05K 1/189; H10K 59/1201; H10K 59/1213; H10K 59/872; H10K 59/8794; H10K 59/88; H05K 2201/10128

(57) ABSTRACT

A display device includes: a display module which displays an image; and an accommodating container which accommodates the display module therein. The display module includes: a cover panel disposed on a lower surface of the display panel; a flexible circuit board connected to each of the display panel and the cover panel; and a part disposed on a lower surface of the cover panel. The cover panel includes a first layer disposed opposite to the display panel, a second layer disposed on the first layer, a third layer disposed on the second layer, a fourth layer disposed on the third layer, and a fifth layer disposed on the fourth layer. The second layer includes a pad portion connected to the flexible circuit board and a line portion which is spaced apart from the pad portion and is connected to the part.

The application claims priority to Korean patent application No. 10-2024-0146919, filed on Oct. 24, 2024, and all the benefits accruing therefrom under 35 U.S.C. § 119, the content of which in its entirety is herein incorporated by reference.

### BACKGROUND

### 1. Field

The disclosure generally relates to a display device and an electronic device including the display device.

### 2. Related Art

Recently, as interest in information displays is increased, research and development of display devices have been continuously conducted.

### SUMMARY

Embodiments provide a pixel and a display device and an electronic device having the same, in which slimness can be easily implemented.

In accordance with an embodiment of the disclosure, there is provided a display device including: a display module which displays an image; and an accommodating container which accommodates the display module therein. In such an embodiment, the display module includes: a display panel; a cover panel disposed on a lower surface of the display panel; a flexible circuit board connected to each of the display panel and the cover panel; and a part disposed on a lower surface of the cover panel. In such an embodiment, the cover panel includes a first layer disposed opposite to the display panel, a second layer disposed on the first layer, a third layer disposed on the second layer, a fourth layer disposed on the third layer, and a fifth layer disposed on the fourth layer. In such an embodiment, the second layer includes a pad portion connected to the flexible circuit board and a line portion which is spaced apart from the pad portion and is connected to the part.

In an embodiment, the pad portion may include a plurality of conductive pads, and the line portion may include a plurality of circuit lines. In such an embodiment, the conductive pads and the circuit lines may each include copper.

In an embodiment, the first layer may define an opening exposing the pad portion, and cover the circuit lines.

In an embodiment, the part may be disposed directly on a lower surface of the first layer which covers the circuit lines.

In an embodiment, the third layer may be disposed between the conductive pads, and the third layer may be exposed by the opening of the first layer.

In an embodiment, the first layer may be a protective layer, the second layer may be a heat dissipation layer, the third layer may be a strength reinforcing layer, the fourth layer may be a cushion layer, and the fifth layer may be an embossed layer.

In an embodiment, each of the first layer and the third layer may include polyimide and an adhesive layer.

In an embodiment, The second layer may include a first sub-layer and a second sub-layer, where the first sub-player may be disposed between the first layer and the third layer, and the second sub-layer may be disposed between the third layer and the fourth layer.

In an embodiment, the first sub-layer and the second sub-layer may correspond to a heat dissipation layer including copper.

In an embodiment, The first sub-layer and the second sub-layer may be electrically connected to each other through a penetration hole defined through a portion of the third layer.

In an embodiment, the first layer may be a solder resist layer, the second layer may be a heat dissipation layer, the third layer may be a strength reinforcing layer, the fourth layer may be a cushion layer, and the fifth layer may be an embossed layer.

In an embodiment, the cover panel may further include a step difference compensation pattern disposed on a lower surface of the first layer. In such an embodiment, the step difference compensation pattern may be disposed on the lower surface of the first layer to be spaced apart from the part.

In an embodiment, the cover panel may further include a dummy pattern disposed on the lower surface of the first layer. In such an embodiment, the dummy pattern may be disposed to be spaced apart from the step difference compensation pattern and the part.

In an embodiment, the dummy pattern may maintain a distance between the display module and the accommodating container.

In an embodiment, the circuit lines may be arranged along an edge of the second layer.

In an embodiment, the display panel may include: a substrate; a pixel circuit layer disposed on the substrate, where the pixel circuit layer may include a transistor; and a display element layer disposed on the pixel circuit layer, where the display element layer may include a light emitting element which emits light.

In accordance with another embodiment of the disclosure, there is provided an electronic device including: a processor configured to provide input image data to a display device; and the display device configured to display an image, based on the input image data. In such an embodiment, the display device includes: a display panel; a cover panel disposed on a lower surface of the display panel; a flexible circuit board connected to each of the display panel and the cover panel; and a part disposed on a lower surface of the cover panel. In such an embodiment, the cover panel includes a protective layer, a heat dissipation layer, a strength reinforcing layer, a cushion layer, and an embossed layer, which are sequentially stacked in a direction opposite to the display panel. In such an embodiment, the heat dissipation layer includes copper. In such an embodiment, the heat dissipation layer includes a pad portion connected to the flexible circuit board and a line portion which is spaced apart from the pad portion and is connected to the part.

In an embodiment, the heat dissipation layer may include a first area, in which the pad portion is disposed, and a second area, in which the line portion is disposed. In such an embodiment, the pad portion may define a plurality of conductive pads, and the line portion may include a plurality of circuit lines.

In an embodiment, the protective layer and the strength reinforcing layer may include polyimide. In such an embodiment, the protective layer may include an opening exposing the first area, and cover the line portion.

In an embodiment, the part may be disposed directly on a low surface of the protective layer which covers the circuit lines.

### BRIEF DESCRIPTION OF THE DRAWINGS

The above and other features of embodiments of the invention will become more apparent by describing in further detail embodiments thereof with reference to the accompanying drawings.

FIG. 1 is a schematic perspective view illustrating a display device in accordance with embodiments of the disclosure.

FIG. 2 is a schematic exploded perspective view illustrating a display device in accordance with embodiments of the disclosure.

FIG. 3 is a schematic plan view illustrating a display device in accordance with embodiments of the disclosure.

FIG. 4 is a schematic plan view illustrating a pixel shown in FIG. 3.

FIG. 5 is a schematic sectional view taken along line II-II′ shown in FIG. 4.

FIG. 6 is a schematic sectional view taken along line I-I′ shown in FIG. 3.

FIG. 7 is a schematic sectional view illustrating the display device shown in FIG. 6 in a state in which a flexible circuit board is bent.

FIG. 8 is a schematic sectional view illustrating a portion of a cover panel shown in FIG. 7.

FIG. 9 is a schematic perspective view illustrating the cover panel shown in FIG. 8 when viewed from the bottom.

FIG. 10 is a schematic enlarged plan view of area EA shown in FIG. 9.

FIG. 11 is a view in which a first layer is omitted in FIG. 10.

FIG. 12 is a schematic flowchart illustrating an embodiment of a method of manufacturing the cover panel shown in FIG. 9.

FIGS. 13 to 17 are schematic plan views illustrating processes of the method of manufacturing the cover panel shown in FIG. 9.

FIG. 18 and FIG. 19 are perspective views schematically illustrating a cover panel in accordance with embodiments of the disclosure.

FIG. 20 is a schematic plan view illustrating a lower surface of a second layer of the cover panel shown in FIG. 9.

FIG. 21 and FIG. 22 are plan views schematically illustrating a lower surface of the cover panel in accordance with embodiments of the disclosure.

FIG. 23 is a schematic block diagram illustrating an electrode device in accordance with embodiments of the disclosure.

FIG. 24 is a schematic view illustrating an embodiment in which the electronic device shown in FIG. 23 is implemented as a smartphone.

FIG. 25 is a schematic view illustrating an embodiment in which the electronic device shown in FIG. 23 is implemented as a tablet PC.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

In the drawing figures, dimensions may be exaggerated for clarity of illustration. It will be understood that when an element is referred to as being “between” two elements, it can be the only element between the two elements, or one or more intervening elements may also be present.

In the entire specification, when an element is referred to as being “connected” or “coupled” to another element, it can be directly connected or coupled to the another element or be indirectly connected or coupled to the another element with one or more intervening elements interposed therebetween.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from X, Y, and Z” can be construed as X only, Y only, Z only, or any combination of two or more items X, Y, and Z (e.g., XYZ, XYY, YZ, ZZ).

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Spatially relative terms, such as “below,” “above,” and the like, may be used herein for ease of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the exemplary term, “above,” may encompass both an orientation of above and below. The apparatus may be otherwise oriented (e.g., rotated 90 degrees or at other orientations) and the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In addition, the embodiments of the disclosure are described here with reference to schematic diagrams of ideal embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof are not intended to illustrate the precise shape of a region and are not intended to limit the scope of the present claims.

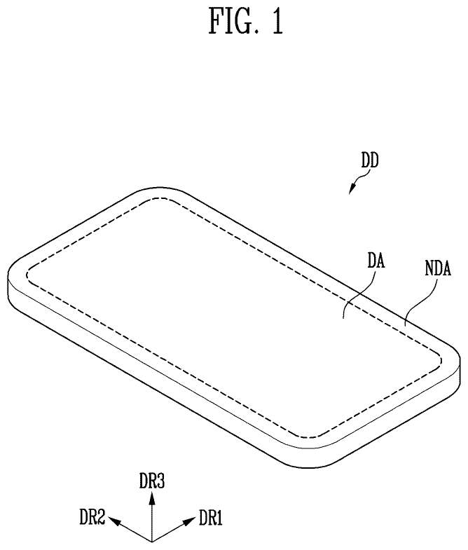

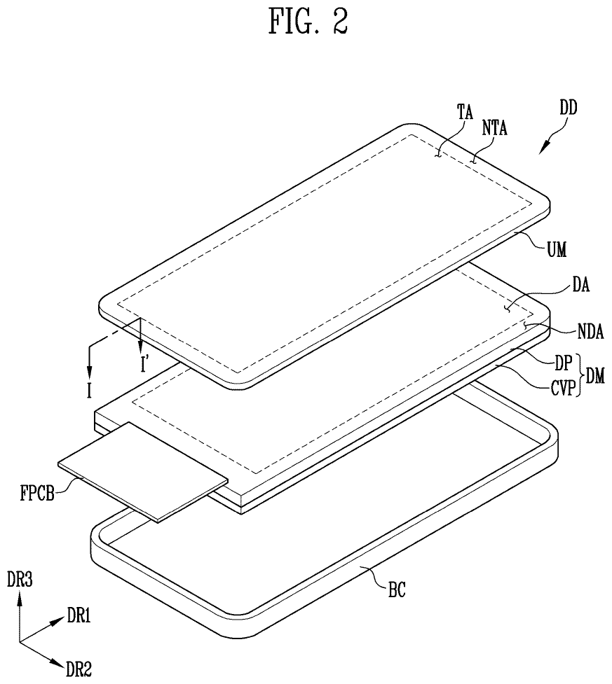

FIG. 1 is a schematic perspective view illustrating a display device DD in accordance with embodiments of the disclosure. FIG. 2 is a schematic exploded perspective view illustrating a display device in accordance with embodiments of the disclosure.

Referring to FIG. 1 and FIG. 2, an embodiment of the display device DD may display an image. The display device DD may refer to nay electronic device which includes a display surface. For example, a television, a notebook computer, a monitor, an advertisement board, Internet of things (IOT), a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation system, a game device, a digital camera, a camcorder, and the like, which provide display surfaces, may be included in the display device DD, but the disclosure is not limited thereto.

The display device DD may be a flat panel display device, a flexible display device, a curved display device, a foldable display device, a bendable display device, or a rollable display device. Also, the display device DD may be applied to a transparent display device, a head-mounted display device, a wearable display device, and the like.

The display device DD may include a display panel DP which provides a display surface. Examples of the display panel DP may include an inorganic light emitting diode display panel, an organic light emitting diode display panel, a quantum dot light emitting display panel, a plasma display panel, a field emission display panel, and the like, but the disclosure is not limited thereto. Hereinafter, for convenience of description, embodiments where the display panel DP is an organic light emitting diode display panel will be described as an example. However, the disclosure is not limited thereto, and another display panel may be applied as along as the same technical spirit is applicable.

The shape of the display device DD may be variously changed. For example, the display device DD may have various shapes, such as a rectangle, a square, a quadrangle having at least one round corner portion (or vertex), other polygons, and a circle. The shape of a display area DA of the display device DD may also be similar to the entire shape of the display device DD. In FIG. 1 and FIG. 2, embodiments where the display device DD and the display area DA, each of which has a quadrangular shape having round corner portions, are shown as an example.

The display device DD may include the display area DA and a non-display area NDA. The display area DA may be an area in which an image can be displayed, and the non-display area NDA may be an area in which the image is not displayed. The display area DA may be referred to as an active area, and the non-display area NDA may be referred to as an inactive area. The display area DA may be located (or defined) in the middle of the display device DD, but the disclosure is not limited thereto.

The display device DD may include a sensing area and a non-sensing area. The display device DD may not only display an image through the sensing area, but also sense a touch input made on a display surface (or input surface) or sense light incident at the front. The non-sensing area may surround the sensing area. However, this is merely illustrative, and the disclosure is not limited thereto. In some embodiments, a portion of the display area DA may correspond to the sensing area.

At least a portion of the display device DD may have flexibility, and the display device DD may be folded at the portion having the flexibility.

The display device DD may include an upper module UM, a display module DM, and an accommodating container BC.

The upper module UM may be located (or disposed) on the top of the display module DM. In an embodiment, for example, the upper module UM may be located on a front surface of the display module DM, e.g., a surface of the display module DM in a third direction DR3. Here, the third direction DR3 may be a thickness direction of the display module DM. The upper module UM may be in contact with the front surface of the display module DM.

The upper module UM may include a window. The window may be located on the top of the display module DM to protect the display module DM from external impact and allow an image provided from the display module DM to be transmitted through a transmission area TA. The upper module DM (or the window) may include the transmission area TA and a non-transmission area NTA. The transmission area TA may have a shape corresponding to the display area DA. In an embodiment, for example, an image displayed in the display area DA may be viewed to the outside through the transmission area TA. The non-transmission area NTA may have a shape corresponding to the non-display area NDA. The non-transmission area NTA may be an area having a relatively low light transmission as compared with the transmission area TA. However, the disclosure is not limited thereto, and the non-transmission area NTA may be omitted.

The display module DM may be located between the upper module UM and the accommodating container BC.

The display module DM may include the display panel DP, a cover panel CVP, and a flexible circuit board FPCB.

The display panel DP may display an image. Examples of the display panel DP may include an inorganic light emitting diode display panel, an organic light emitting diode display panel, a quantum dot light emitting display panel, a plasma display panel, a field emission display panel, and the like, but the disclosure is not limited thereto. The display panel DP may include the display area DA and the non-display area NDA.

A touch sensor may be located between the display panel DP and the upper module UM. The touch sensor may be located directly on a surface on which an image is displayed in the display module DM to receive a touch input of a user.

The flexible circuit board FPCB may be connected (or attached) to an end portion of the display panel DP to provide a driving signal and a voltage to the display panel DP. In an embodiment, for example, the driving signal may be a signal for allowing an image to be displayed from the display panel DP, and the voltage may be a driving voltage used to drive the display panel DP. The flexible circuit board FPCB may be located on a lower surface (or second surface) of the display panel DP while being folded along a side surface of an upper surface (or first surface) of the display panel DP. The flexible circuit board FPCB may be connected to a pad portion located in a lower surface to process various signals input from a part mounted on the lower surface of the cover panel CVP and output the processed signals to the display panel DP. In such an embodiment, the flexible circuit board FPCB may be attached to each of the display panel DP and the cover panel CVP, to be electrically connected to the each of the display panel DP and the cover panel CVP.

The cover panel CVP may be provide on the lower surface of the display panel DP, i.e., a surface on which no image is displayed. The cover panel CVP may protect the display panel DP from external impact or the like. In some embodiments, the cover panel CVP may include a heat dissipation layer including conductive pads and circuit lines, to be electrically connected to the flexible circuit board FPCB, the part, or the like. The cover panel CVP will be described in greater detail later.

The accommodating container BC may accommodate the display module DM therein. The accommodating container BC may be coupled to the upper module UM to define an appearance of the display device DD. The accommodating container BC may include a material having a relatively high hardness (high rigidity or stiffness measured using Young's modulus). In an embodiment, for example, the accommodating container BC may include a plurality of frames and/or a plurality of plates, which include or are made of glass, plastic and/or metal. The accommodating container BC may absorb impact applied from the outside and effectively prevent a foreign matter, moisture or the like, infiltrating into the display module DM, thereby protecting components accommodated in the accommodating container BC.

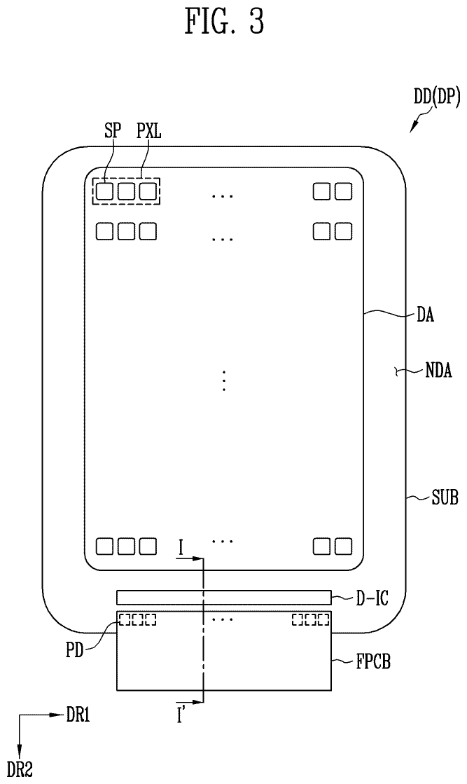

FIG. 3 is a schematic plan view illustrating a display device DD accordance with embodiments of the disclosure. In FIG. 3, a structure of the display device DD, e.g., a display panel DP provided in the display device DD is schematically illustrated, based on a display area DA in which an image is displayed.

Referring to FIG. 3, an embodiment of the display device DD (or the display panel DP) may include a substrate SUB, sub-pixels SP, a flexible circuit board FPCB, and a driver D-IC.

The substrate SUB may include the display area DA and a non-display area NDA. The display area DA may be an area in which the sub-pixels SP (or pixels PXL) are provided. A sub-pixel SP may include at least one light emitting element. In an embodiment, for example, the light emitting element may include a light emitting layer (e.g., an organic light emitting layer). A portion at which light is emitted by the light emitting element may be defined as an emission area. The display area DD may drive the sub-pixels SP, corresponding to image data, thereby displaying an image in the display area DA.

The sub-pixel SP may be arranged in the display area DA on the substrate SUB. The sub-pixels SP may be arranged in a matrix form along a first direction DR1 and a second direction DR2 crossing the first direction DR1, but the arrangement form of the sub-pixels SP is not limited thereto. In an embodiment, for example, the sub-pixels SP may be arranged in a zigzag form along the first direction DR1 and the second direction DR2. In an embodiment, for example, the sub-pixels SP may be arranged in a PENTILE™ form. The first direction DR1 may be a row direction and the second direction DR2 may be a column direction.

Two or more sub-pixels SP among a plurality of sub-pixels SP may constitute a pixel PXL.

The driver D-IC may be located in the non-display area NDA on the substrate SUB. The driver D-IC may include a driving chip. An area of the non-display area NDA, in which the driver D-IC is located, may be located between the display area DA and an area of the non-display area NDA, in which the flexible circuit board FPCB is attached.

The driver D-IC may include driving elements for driving the sub-pixels SP. In an embodiment, for example, the driver D-IC may include a scan driving circuit which generates a plurality of scan signals and transfers the scan signals to scan lines, a data driving circuit which transfers a data signal to data lines, an emission control driving circuit which transfers an emission control signal to emission control lines, and the like. However, the disclosure is not limited thereto.

The driver D-IC may be located on an upper surface of the display panel DP. In an embodiment, for example, the driver D-IC may be located in the non-display area NDA of the display panel DP. In FIG. 3, an embodiment having a structure in which the driver D-IC is located on the display panel DP is illustrated as an example, but the disclosure is not limited thereto. In some embodiments, the driver D-IC may be located on the flexible circuit board FPCB.

The flexible circuit board FPCB may be located on the upper surface of the display panel DP. The flexible circuit board FPCB may be electrically connected to the driver D-IC. The flexible circuit board FPCB may be attached to at least one of components included in the display panel DP to be electrically connected to the driver D-IC of the display panel DP. In an embodiment, for example, the flexible circuit board FPCB may be attached to an end portion of the substrate SUB. The flexible circuit board FPCB may be connected to pads PD arranged at the end portion of the substrate SUB to be electrically connected to the driver D-IC through the pads PD. The pads PD may interface the display panel DP to other components of the display device DD.

The flexible circuit board FPCB may include a plurality of driving elements and signal lines. The plurality of driving elements may include electronic elements which converts a signal input from the outside into a signal for the driver D-IC or a signal to drive the display panel DP.

Components, such as the flexible circuit board FPCB may be bent in a “⊏” shape along an end portion of the display panel DP and then be located on a lower surface of the display panel DP to maximize the efficiency of a space and not to be viewed by a user.

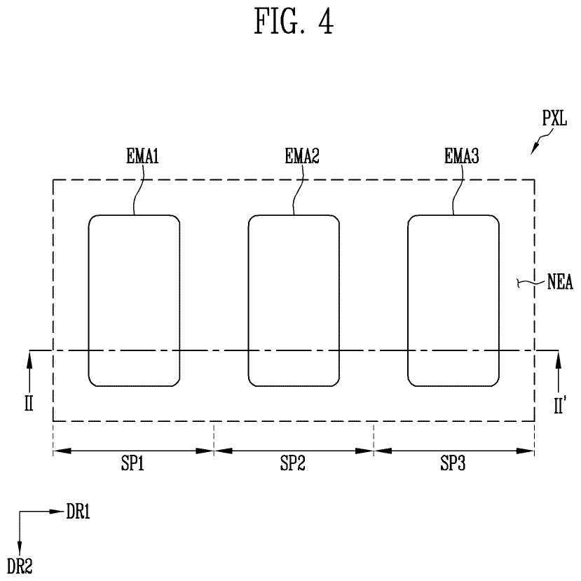

FIG. 4 is a schematic plan view illustrating the pixel PXL shown in FIG. 3.

Referring to FIG. 3 and FIG. 4, in an embodiment, the pixel PXL may include a first sub-pixel SP1, a second sub-pixel SP2, and a third sub-pixel SP3, which are arranged along the first direction DR1.

The first sub-pixel SP1 may include a first emission area EMA1 and a non-emission area NEA at the periphery of the first emission area EMA1. The second sub-pixel SP2 may include a second emission area EMA2 and the non-emission area NEA at the periphery of the second emission area EMA2. The third sub-pixel SP3 may include a third emission area EMA3 and the non-emission area NEA at the periphery of the third emission area EMA3.

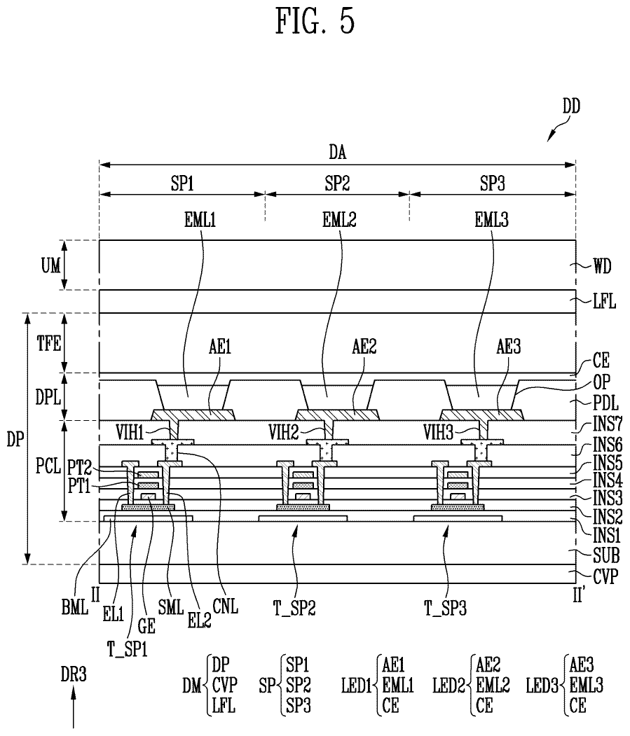

The first emission area EMA1 may be an area in which light is emitted from a light emitting layer corresponding to the first sub-pixel SP1. The second emission area EMA2 may be an area in which light is emitted from a light emitting layer corresponding to the second sub-pixel SP2. The third emission area EMA3 may be an area in which light is emitted from a light emitting layer corresponding to the third sub-pixel SP3. Each emission area may be understood as an opening (see “OP” shown in FIG. 5) of a pixel defining layer (see “PDL” shown in FIG. 5), which corresponds to each of the first to third sub-pixels SP1 to SP3.

The first sub-pixel SP1, the second sub-pixel SP2, and the third sub-pixel SP3 may substantially have a same size or area (e.g., planar area) as each other, but the disclosure is not limited thereto. In some embodiments, the second sub-pixel SP2 may have a size or area larger than a size or area of the first sub-pixel SP1, and the third sub-pixel SP3 may have a size or area larger than the size or area of the second sub-pixel SP2.

The first sub-pixel SP1, the second sub-pixel SP2, and the third sub-pixel SP3 may have a polygonal shape in a plan view or when viewed in the third direction DR3, which is perpendicular to the plane defined by the first direction DR1 and the second direction DR2. In an embodiment, for example, the first sub-pixel SP1, the second sub-pixel SP2, and the third sub-pixel SP3 may have a polygonal shape or a hexagonal shape, but the disclosure is not limited thereto. In some embodiments, the first sub-pixel SP1, the second sub-pixel SP2, and the third sub-pixel SP3 may have a circular shape, a semi-elliptical shape, or the like in a plan view.

The arrangement of the sub-pixels, which is shown in FIG. 4, is merely illustrative, and embodiments are not limited thereto. Each pixel PXL may include two or more sub-pixels, and the sub-pixels may be arranged in various manners. Each of the sub-pixels may have various shapes, and each of emission areas of the sub-pixels may also have various shapes.

FIG. 5 is a schematic sectional view taken along line II-II′ shown in FIG. 4.

In FIG. 5, for convenience of illustration and description, a sectional structure (or stacked structure) of the display device DD is schematically illustrated based on the sub-pixels SP included in the display device DD, and a thickness direction of a substrate SUB is indicated as the third direction DR3.

Referring to FIG. 4 and FIG. 5, an embodiment of the display device DD may include a display module DM and an upper module UM.

The display module DM may include a display panel DP, a cover panel CVP, and a light functional layer LFL.

The display panel DP may include at least one sub-pixel SP arranged in the display area DA. In an embodiment, for example, the display module DM may include a first sub-pixel SP1, a second sub-pixel SP2, and a third sub-pixel SP3, which are arranged in the display area DA. In embodiments, the first sub-pixel SP1 may be a red sub-pixel, the second sub-pixel SP2 may be a green sub-pixel, and the third sub-pixel SP3 may be a blue sub-pixel. However, the disclosure is not limited thereto. Hereinafter, when the first sub-pixel SP1, the second sub-pixel SP2, and the third sub-pixel SP3 are inclusively designated, the first sub-pixel SP1, the second sub-pixel SP2, and the third sub-pixel SP3 are designated as a sub-pixel SP and/or sub-pixels SP.

Each of the first sub-pixel SP1, the second sub-pixel SP2, and the third sub-pixel SP3 may include the substrate SUB, a pixel circuit layer PCL, a display element layer DPL, a thin film encapsulation layer TFE, and a window WD.

The window WD may be a component included in the upper module UM, and be located on the display panel DP to protect the display panel DP from external impact. The window WD may have a multi-layer structure including (or selected from) a glass substrate, a plastic film, or a plastic substrate. The multi-layer structure may be formed through a continuous process or an adhesion process using an adhesive layer. The whole or a portion of the window WD may have flexibility.

The substrate SUB may include a transparent insulating material to enable light to be transmitted therethrough. The substrate SUB may be a rigid substrate or a flexible substrate.

The pixel circuit layer PCL of the sub-pixel SP may be located on the substrate SUB. At least one insulating layer may be located in the pixel circuit layer PCL. The insulating layer may include a first insulating layer INS1, a second insulating layer INS2, a third insulating layer INS3, a fourth insulating layer INS4, a fifth insulating layer INS5, a sixth insulating layer INS6, and a seventh insulating layer INS7, which are sequentially stacked on the substrate SUB along the third direction DR3. The insulating layer located in the pixel circuit layer PCL is not limited to the above-described embodiment, another insulating layer may be added, or some insulating layers may be omitted.

The first insulating layer INS1 may be located on the substrate SUB. The first insulating layer INS1 may effectively prevent an impurity from being diffused into circuit elements (or driving elements), e.g., transistors, which constitute a pixel circuit. The first insulating layer INS1 may be an inorganic layer including an inorganic material (or substance). The first insulating layer INS1 may include at least one selected from silicon nitride (SiNₓ), silicon oxide (SiOₓ), silicon oxynitride (SiOₓN_{y}), or aluminum oxide (AlOₓ). The first insulating layer INS1 may be provided as (or defined by) a single layer, but be provided as a multi-layer including at least two layers. In another embodiment, the first insulating layer INS1 may be omitted according to a material of the substrate SUB, a process condition, or the like.

The second insulating layer INS2 may be located on the first insulating layer INS1. The second insulating layer INS2 and the first insulating layer INS1 may include a same material as each other, or the second insulating layer INS2 may include at least one from the materials listed above as the material constituting the first insulating layer INS1. In an embodiment, for example, the second insulating layer INS2 may be an inorganic layer including an inorganic material.

The third insulating layer INS3 may be located on the second insulating layer INS2. The third insulating layer INS3 and the first insulating layer INS1 may include a same material as each other, or the third insulating layer INS3 may include at least one from the materials listed above as the material constituting the first insulating layer INS1.

The fourth insulating layer INS4 may be located on the third insulating layer INS3. The fourth insulating layer INS4 may be an inorganic layer including an inorganic material or an organic layer including an organic material.

The fifth insulating layer INS5 may be located on the fourth insulating layer INS4. The fifth insulating layer INS5 and the first insulating layer INS1 may include a same material as each other, or the fifth insulating layer INS5 may include at least one from the materials listed above as the material constituting the first insulating layer INS1.

The sixth insulating layer INS6 (or first via layer) may be located on the fifth insulating layer INS5. The sixth insulating layer INS6 may be an inorganic layer including an inorganic material or an organic layer including an organic material. The inorganic layer may include, for example, at least one selected from silicon oxide, silicon nitride, silicon oxynitride, or aluminum oxide. The organic layer may include, for example, at least one selected from acrylic resin, epoxy resin, phenolic resin, polyamide resin, polyimide resin, unsaturated polyester resin, poly-phenylene ether resin, poly-phenylene sulfide resin, or benzocyclobutene resin. In an embodiment, the sixth insulating layer INS6 may be an organic layer including an organic material.

The seventh insulating layer INS7 (or second via layer) may be located on the sixth insulating layer INS6. The seventh insulating layer INS7 and the sixth insulating layer INS6 may include a same material, or the seventh insulating layer INS7 may include at least one from the materials listed above as the material constituting the sixth insulating layer INS6. In an embodiment, for example, the seventh insulating layer INS7 may be an organic layer including an organic material.

Circuit elements of each of the first to third sub-pixels SP1 to SP3 may be located in the pixel circuit layer PCL. In an embodiment, for example, a transistor T_SP1 of the first sub-pixel SP1, a transistor T_SP2 of the second sub-pixel SP2, and a transistor T_SP3 of the third sub-pixel SP3 may be located in the pixel circuit layer PCL.

The transistor T_SP1 of the first sub-pixel SP1 may include a semiconductor pattern SML, a gate electrode GE, a first terminal EL1, and a second terminal EL2.

The gate electrode GE may be located on the second insulating layer INS2 to be covered by the third insulating layer INS3. The gate electrode GE may overlap a portion of the semiconductor pattern SML. In an example, the gate electrode GE may overlap an active pattern of the semiconductor pattern SML.

A first pattern PT1 and a second pattern PT2 may be further located in the pixel circuit layer PCL. The first pattern PT1 may be located between the third insulating layer INS3 and the fourth insulating layer INS4, and the second pattern PT2 may be located between the fourth insulating layer INS4 and the fifth insulating layer INS5. In some embodiments, the first pattern PT1 may overlap the gate electrode GE while the third insulating layer INS3 is interposed between the first pattern PT1 and the gate electrode GE, thereby forming a capacitor. The second pattern PT2 may be used as signal lines, a connection means, or the like, electrically connected to transistors.

The semiconductor pattern SML may be located on the first insulating layer INS1 to be covered by the second insulating layer INS2. The semiconductor pattern SML may be a semiconductor layer including or made of poly-silicon, amorphous silicon, an oxide semiconductor, or the like. The semiconductor pattern SML may include the active pattern, a first contact region, and a second contact region. The active pattern, the first contact region, and the second contact region may include a semiconductor layer undoped or doped with an impurity. In an embodiment, for example, the first region and the second region may include a semiconductor layer doped with the impurity, and the active pattern may be a region doped with the impurity at a relatively low concentration as compared with the first and second contact regions. Accordingly, a conductivity of the first and second contact regions may be greater than a conductivity of the active pattern. The first and second contact regions may be source/drain regions (or source/drain electrodes) of the transistor T_SP1 of the first sub-pixel SP1.

The active pattern of the semiconductor pattern SML may be a channel region as a region overlapping the gate electrode GE. The first contact region of the semiconductor pattern SML may be in contact with an end of the active pattern. The first contact region may be electrically connected to the first terminal EL1. The second contact region of the semiconductor pattern SML may be in contact with an opposite end of the active pattern. The second contact region may be electrically connected to the second terminal EL2.

The first terminal EL1 may be located on the fifth insulating layer INS5. The first terminal EL1 may be in contact with the first contact region of the semiconductor pattern SML.

The second terminal EL2 may be located on the fifth insulating layer INS5, and be spaced apart from the first terminal EL1. The second terminal EL2 may be in contact with the second contact region of the semiconductor pattern SML. The second terminal EL2 may be electrically connected to a connection line CNL located on the sixth insulating layer INS6.

In some embodiments, a bottom metal pattern BML may be located under the transistor T_SP1 of the first sub-pixel SP1. The bottom metal pattern BML may be a dummy conductive layer located between the substrate SUB and the first insulating layer INS1.

Each of the transistor T_SP2 of the second sub-pixel SP2 and the transistor T_SP3 of the third sub-pixel SP3 may be configured substantially identically to the transistor T_SP1 of the first sub-pixel SP1.

The display element layer DPL may be located on the pixel circuit PCL. A light emitting element and a pixel defining layer PDL may be located in the display element layer DPL. The light emitting element may include an anode electrode, a light emitting layer, and a cathode electrode CE. A first light emitting element LED1 may be provided in the first sub-pixel SP1, a second light emitting element LED2 may be provided in the second sub-pixel SP2, and a third light emitting element LED3 may be provided in the third sub-pixel SP3.

A first anode electrode AE1 may be located on the pixel circuit layer PCL of the first sub-pixel SP1, a second anode electrode AE2 may be located on the pixel circuit layer PCL of the second sub-pixel SP2, and a third anode electrode AE3 may be located on the pixel circuit layer PCL of the third sub-pixel SP3. The first anode electrode AE1 may be electrically connected to the transistor T_SP1 of the first sub-pixel SP1 through a first via hole VIH1 defined or formed through the seventh insulating layer INS7, the second anode electrode AE2 may be electrically connected to the transistor T_SP2 of the second sub-pixel SP2 through a second via hole VIH2 defined or formed through the seventh insulating layer INS7, and the third anode electrode AE3 may be electrically connected to the transistor T_SP3 of the third sub-pixel SP3 through a third via hole VIH3 defined or formed through the seventh insulating layer INS7.

The first anode electrode AE1, the second anode electrode AE2, and the third anode electrode AE3 may respectively have shapes similar to shapes of the first, second, and third emission areas EMA, EMA2, and EMA3 as shown in FIG. 4 when viewed in the third direction DR3 or in a plan view. In an embodiment, for example, the first anode electrode AE1 may have a shape similar to a shape of the first emission area EMA1 when viewed in the third direction DR3, the second anode electrode AE2 may have a shape similar to a shape of the second emission area EMA2 when viewed in the third direction DR3, and the third anode electrode AE3 may have a shape similar to a shape of the third emission area EMA3 when viewed in the third direction DR3. However, the disclosure is not limited thereto.

Each of the first to third anode electrodes AE1 to AE3 may be electrically connected to a corresponding transistor to be supplied with a driving current. Each of the first to third anode electrodes AE1 to AE3 may include an opaque conductive material capable of reflecting light, but the disclosure is not limited thereto. In some embodiments, the first to third anode electrodes AE1 to AE3 may include a transparent conductive material.

The pixel defining layer PDL may be located on the first to third anode electrodes AE1 to AE3. The pixel defining layer PDL may define an opening OP exposing each of a portion of the first anode electrode AE1, a portion of the second anode electrode AE2, and a portion of the third anode electrode AE3. The pixel defining layer PDL may be a structure defining (or partitioning) the emission area of each of the first to third sub-pixels SP1 to SP3. In an embodiment, for example, the pixel defining layer PDL may define the first emission area EMA1 of the first sub-pixel SP1, the second emission area EMA2 of the second sub-pixel SP2, and the third emission area EMA3 of the third sub-pixel SP3.

The pixel defining layer PDL may be an organic insulating layer including an organic material. A first light emitting layer EML1 may be located on the first anode electrode AE1 exposed by an opening OP of the pixel defining layer PDL, a second light emitting layer EML2 may be located on the second anode electrode AE2 exposed by another opening OP of the pixel defining layer PDL, and a third light emitting layer EML3 may be located on the third anode electrode AE3 exposed by still another opening OP of the pixel defining layer PDL. Each of the first to third light emitting layers EML1 to EML3 may have a multi-layer structure including a hole injection layer, a hole transport layer, an organic light emitting layer, an electron transport layer, an electron injection layer, and the like. However, the disclosure is not limited thereto.

The first to third light emitting layers EML1 to EML3 may include at least one of light emitting materials that emit light of different colors according to a corresponding sub-pixel SP.

The cathode electrode CE may be located on the first to third light emitting layers EML1 to EML3 and the pixel defining layer PDL. The cathode electrode CE may be a common layer commonly provided in the first to third sub-pixels SP1 to SP3. The cathode electrode CE may be provided in a plate shape throughout the entire display area DA.

The cathode electrode CE may be a thin metal layer having a thickness thick enough to enable light emitted from a corresponding light emitting layer to be transmitted therethrough. The cathode electrode CE may include a metal material to have a relatively thin thickness or include a transparent conductive material. In an embodiment, the cathode electrode CE may include at least one selected from various transparent conductive materials including indium tin oxide, indium zinc oxide, indium tin zinc oxide, aluminum zinc oxide, gallium zinc oxide, zinc tin oxide, or gallium tin oxide. In another embodiment, the cathode electrode CE may include at least one selected from magnesium, silver, or any mixture thereof. However, the material of the cathode electrode CE is not limited to the above-described embodiment.

The first anode electrode AE1, the first light emitting layer EML1, and a portion of the cathode electrode CE, which overlaps the first anode electrode AE1 in the third direction DR3, may constitute the first light emitting element LED1. The second anode electrode AE2, the second light emitting layer EML2, and a portion of the cathode electrode CE, which overlaps the second anode electrode AE2 in the third direction DR3, may constitute the second light emitting element LED2. The third anode electrode AE3, the third light emitting layer EML3, and a portion of the cathode electrode CE, which overlaps the third anode electrode AE3 in the third direction DR3, may constitute the third light emitting element LED3.

The thin film encapsulation layer TFE may be located over the cathode electrode CE. The thin film encapsulation layer TFE may cover the display element layer DPL. The thin film encapsulation layer TFE may effectively prevent oxygen and/or moisture from infiltrating into the display element layer DPL. In an embodiment, the thin film encapsulation layer TFE may have a structure in which one or more inorganic layers and one or more organic layers are alternately stacked.

The light functional layer LFL may be located between the display panel DP and the upper module UM (or the window WD). The light functional layer LFL may include a polarizing film, a microlens, and/or a prism film, but the disclosure is not limited thereto. A bonding layer including an adhesive material may be located on a lower surface of the light functional layer LFL, and the light functional layer LFL may be attached to an upper surface of the display panel DP through the bonding layer. The bonding layer may include an optically clear bonding layer, a bonding transparent resin, or the like. In an embodiment, for example, the adhesive material may include an optically clear pressure sensitive adhesive, or the like.

The cover panel CVP may be located on a lower surface of the display panel DP. In an embodiment, for example, the cover panel CVP may be located on a lower surface of the substrate SUB of the display panel DP. The cover panel CVP may perform a heat dissipation function, an electromagnetic wave shielding function, a buffering function, and/or a strength reinforcing function.

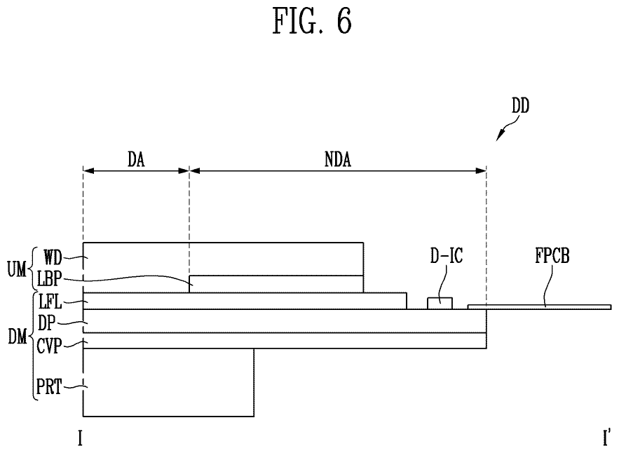

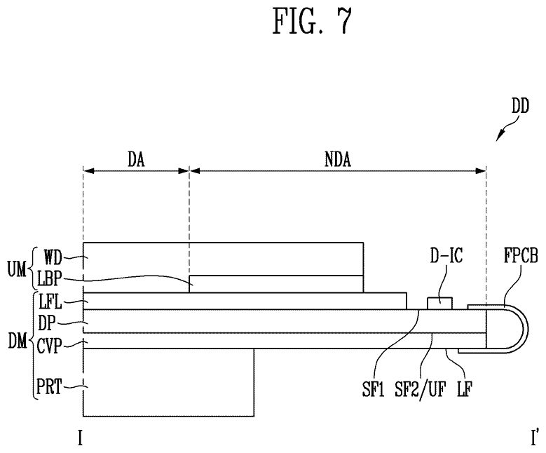

FIG. 6 is a schematic sectional view taken along line I-I′ shown in FIG. 3. FIG. 7 is a schematic sectional view illustrating the display device shown in FIG. 6 in a state in which the flexible circuit board FPCB is.

In description of the embodiments shown in FIGS. 6 and 7, elements different from those described above will be manly described to avoid redundancy.

Referring to FIGS. 3, 6, and 7, an embodiment of the display device DD may include a display module DM and an upper module UM.

The upper module UM may include a window WD and a light blocking pattern LBP.

The light blocking pattern LBP may be an organic layer including a colored organic material. In an embodiment, for example, the light blocking pattern LBP may be a black organic layer film. The light blocking pattern LBP may be formed on a lower surface of the window WD, using a coating method. The light blocking pattern LBP may be located in an area of the window WD. In an embodiment, for example, the light blocking pattern LBP may be formed to surround the circumference of the window WD. The light blocking pattern LBP may be located in the non-display area NDA of the display device DD.

The display module DM may include a display panel DP, a light functional layer LFL, a cover panel CVP, a part PRT, a flexible circuit board FPCB, and a driver D-IC.

The light functional layer LFL may be located on a first surface SF1 (or upper surface) of the display panel DP. The driver D-IC may be located on the first surface SF1 of the display panel DP. The driver D-IC may be located on the first surface SF1 of the display panel DP to be spaced apart from the light functional layer LFL.

The cover panel CVP may be located on a second surface SF2 (or lower surface) of the display panel DP. The cover panel CVP may include a lower surface LF and an upper surface UF, which are opposite to each other in the third direction DR3. The upper surface UF of the cover panel CVP may face (or be in contact with) the second surface SF2 of the display panel DP.

A side of the flexible circuit board FPCB may be attached to the first surface SF1 of the display panel DP, and an opposite side of the flexible circuit board FPCB may be attached to the lower surface LF of the cover panel CVP. In an embodiment, for example, the side of the flexible circuit board FPCB may be attached to an upper surface of a substrate of the display panel DP, and the opposite side of the flexible circuit board FPCB may be attached directly on a pad portion of the cover panel CVP to be electrically connected to the pad portion. The flexible circuit board FPCB may be bent in a way such that the opposite side of the flexible circuit board FPCB is located on the lower surface LF of the cover panel CVP.

The part PRT may be located on the lower surface LF of the cover panel CVP. In an embodiment, for example, the part PRT may be mounted directly on the lower surface LR of the cover panel CVP. In embodiments, the part PRT may include a control module, a wireless communication module, an image input module, a sound input module, a sound output module, an external interface module, or the like.

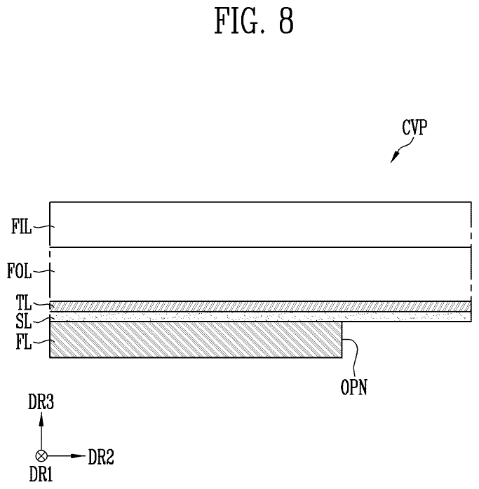

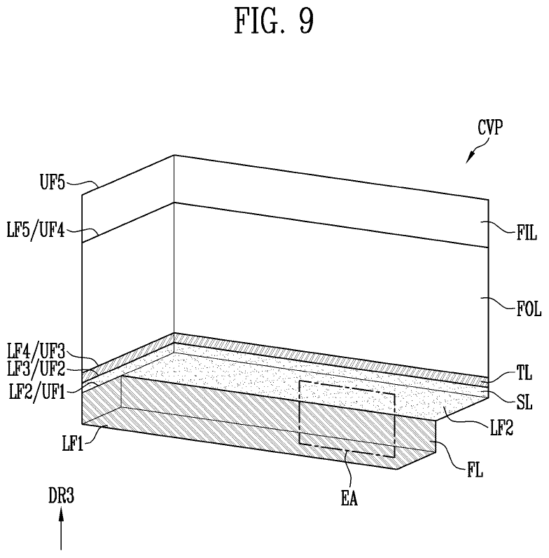

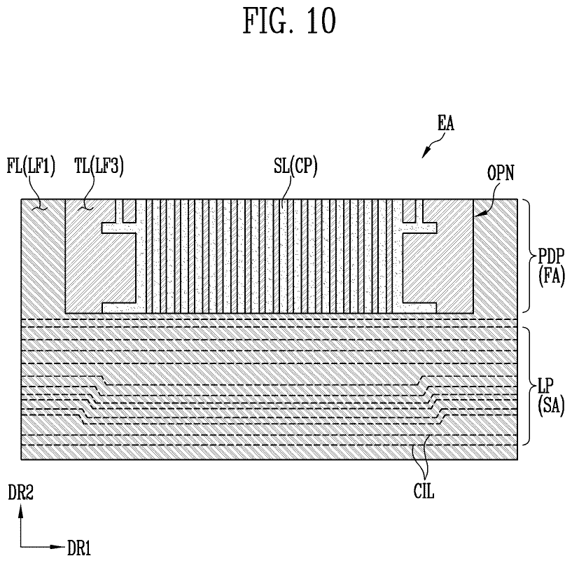

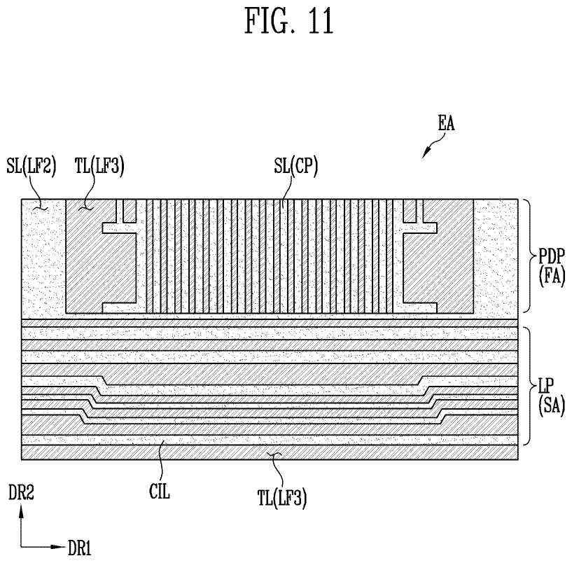

FIG. 8 is a schematic sectional view illustrating a portion of the cover panel CVP shown in FIG. 7. FIG. 9 is a schematic perspective view illustrating the cover panel CVP shown in FIG. 8 when viewed from the bottom. FIG. 10 is a schematic enlarged plan view of area EA shown in FIG. 9. FIG. 11 is a view in which a first layer FL is omitted in FIG. 10.

Referring to FIGS. 7 to 11, in an embodiment, the cover panel CVP may be located on the lower surface of the display panel (see “DP” shown in FIG. 7).

The cover panel CVP may include a first layer FL, a second layer SL, a third layer TL, a fourth layer FOL, and a fifth layer FIL, which are sequentially stacked along the third direction DR3. The second layer SL may be located on the first layer FL, the third layer TL may be located on the second layer SL, the fourth layer FOL may be located on the third layer TL, and the fifth layer FIL may be located on the fourth layer FOL. The first layer FL may be located on the lower surface (see “LF” shown in FIG. 7) of the cover panel CVP, and the fifth layer FIL may be located on the upper surface (see “UF” shown in FIG. 7) of the cover panel CVP. That is, the lower surface of the first layer FL may define the lower surface (see “LF” shown in FIG. 7) of the cover panel CVP, and the upper surface of the fifth layer FIL may define the upper surface (see “UF” shown in FIG. 7) of the cover panel CVP.

In embodiments, the fifth layer FIL may be an embossed layer. The fifth layer FIL may include a fifth lower surface LF5 and a fifth upper surface UF5, which are opposite to each other in a thickness of the cover panel CVP (or the third direction DR3). The fifth upper surface UF5 may be in contact with the display panel DP. The fifth upper surface UF5 may be the upper surface UF of the cover panel CVP. An embossed shape may be formed at the fifth upper surface UF5 of the fifth layer FIL. In case that the embossed shape is formed at the fifth upper surface UF5 of the fifth layer FIL, the embossed shape may serve as an air path such that bubble is reduced when the cover panel CVP including the fifth layer FIL is attached to the second surface (see “SF2” shown in FIG. 7) (or the lower surface) of the display panel DP. In a state where the fifth layer FIL is completely attached to the second surface SF2 of the display panel DP, the embossed shape of the fifth upper surface UF5 of the fifth layer FIL may collapse and become flat. The fifth layer FIL may include or be made of resin or the like, but the disclosure is not limited thereto. The fifth layer FIL may have a thickness of about 25 micrometers (μm) in the third direction DR3, but the disclosure is not limited thereto.

In embodiments, the fourth layer FOL may be a cushion layer. The fourth layer FOL may be located between the third layer TL and the fifth layer FIL. The fourth layer FOL may include a fourth lower surface LF4 and a fourth upper surface UF4, which are opposite to each other in a thickness direction of the cover panel CVP. The fourth upper surface UF4 may be in contact with the fifth lower surface LF5 of the fifth layer FIL. The fourth layer FOL may absorb external impact, thereby effectively preventing the display device (see “DD” shown in FIG. 7) from being damaged. The fourth layer FOL may be provided as (or defined by) a single layer or a multi-layer including a plurality of stacked layers. The fourth layer FOL may include an elastically deformable material. In an embodiment, for example, the fourth layer FOL may include at least one selected from thermoplastic elastomer, polystyrene, polyolefin, polyurethane thermoplastic elastomer, polyamide, synthetic rubber, polydimethylsiloxane, polybutadiene, polyisobutylene, poly(styrene-butadiene-styrene), polyurethane, polychloroprene, polyethylene, silicon and the like, or combinations thereof. However, the disclosure is not limited thereto. In some embodiments, in the fourth layer FOL, an appropriate material may be selected within a range the material has no influence on image display of the display panel DP among materials having elasticity. The fourth layer FOL may have a thickness of about 122 μm in the third direction DR3, but the disclosure is not limited thereto.

In embodiments, the third layer TL may be a strength reinforming layer. The third layer TL may be located between the fourth layer FOL and the second layer SL. The third layer TL may include a third lower surface LF3 and a third upper surface UF3, which are opposite to each other along the thickness direction of the cover panel CVP. The third upper surface UF3 may be in contact with the fourth lower surface LF4 of the fourth layer FOL. The third layer TL may include or be made of polyimide and an adhesive layer, but the disclosure is not limited thereto. In some embodiments, the third layer TL may include at least one selected form polyethylene terephthalate, polycarbonate, polyethylene, polypropylene, polysulfone, polymethylmethacrylate, triacetyl cellulose, cycloolefin polymer, or the like. The third layer TL may have a thickness of about 12.5 μm in the third direction DR3, but the disclosure is not limited thereto.

In embodiments, the second layer SL may be a heat dissipation layer. The second layer SL may transfer, to the outside, heat generated inside the display device DD, and shield electromagnetic waves, and the like. The second layer SL may include a second lower surface LF2 and a second upper surface UF2, which opposite to each other in the thickness direction of the cover panel CVP. The second upper surface UF2 may be in contact with the third lower surface LF3 of the third layer TL. The second layer SL is one which imparts a heat dissipation effect for the heat generated from the part (see “PRT” shown in FIG. 7) which may be in a relatively high temperature, the display panel DP, and the like. The second layer SL may include a material having high thermal conductivity. In an embodiment, for example, the second layer SL may include or be made of a conductive metal selected from metals, such as copper, silver, gold, aluminum, and nickel, or combinations thereof. In embodiments, the second layer SL may include or be made of copper. Because the second layer SL has conductivity, the second layer SL may have a grounding function together with the heat dissipation function, and protect the second surface SF2 of the display panel DP. The second layer SL2 may have a thickness of about 12 μm in the third direction DR3, but the disclosure is not limited thereto. The second layer SL2 may be provided as a conductive layer as a single layer, but the disclosure is not limited thereto. In some embodiments, the second layer SL may be provided as a multi-layer in which a plurality of conductive layers are stacked.

In embodiments, the first layer FL may be a protective layer and an adhesive layer. The first layer FL may be located between the second layer SL and the part PRT. The first layer FL may include a first lower surface LF1 and a first upper surface UF1, which are opposite to each other in the thickness direction of the cover panel CVP. The first upper surface UF1 may be in contact with the second lower surface LF2 of the second layer SL. The first layer FL may be a plastic film including an adhesive layer. In an embodiment, for example, the first layer FL may include or be made of polyimide and an adhesive layer, but the disclosure is not limited thereto. The first layer FL may be located on the second lower surface LF2 of the second layer SL to protect the second layer SL. The first layer FL may define an opening portion (or opening) OPN exposing a portion of the second lower surface LF2 of the second layer SL.

In an embodiment, as shown in FIG. 10, the second layer SL may include a pad portion PDP and a line portion LP. The second layer SL may include a first area FA in which the pad portion PDP is located and a second area SA in which the line portion LP is located.

The pad portion PDP may include a plurality of conductive pads CP. The conductive pads CP may be located in the first area FA. Each of the conductive pads CP may be arranged to be spaced apart from an adjacent conductive pad CP in the first direction DR1. The third layer TL may be exposed between two adjacent conductive patterns CP. In an embodiment, for example, the third lower surface LF3 of the third layer TL may be exposed between two adjacent conductive pads of the second layer SL.

The pad portion PDP may be exposed to the outside by the opening portion OPN of the first layer FL. The pad portion PDP may be connected to the flexible circuit board (see “FPCB” shown in FIG. 7) bent toward the second surface SF2 of the display panel DP. The pad portion PDP may be connected to the flexible circuit board FPCB through a conductive adhesive layer or the like to be electrically connected to driving elements of the flexible circuit board FPCB.

The line portion LP may include a plurality of circuit lines CIL. The circuit lines CIL may be located in the second area SA, and be arranged to be spaced apart from the conductive pads CP of the pad portion PDP. Each of the circuit lines CIL may be arranged to be spaced apart from adjacent circuit lines. The third layer TL may be located between adjacent circuit line CIL. In an embodiment, for example, the third lower surface LF3 of the third layer TL may be located between adjacent circuit lines CIL.

The line portion LP may be covered by the first layer FL. In an embodiment, for example, the circuit lines CIL of the line portion LP may be covered by the first layer FL. The circuit lines CIL may be connected to the part PRT mounted on the first layer FL. In an embodiment, for example, the circuit lines CIL may be electrically connected to the part PRT.

The conductive pads CP and the circuit lines CIL may include or be made of copper. An area of the second layer SL, which does not include the pad portion PDP (or the conductive pads CP) and the line portion LP (or the circuit lines CIL), may be provided in a plate shape to be used as a heat dissipation layer. The area of the second layer SL, which is used as the heat dissipation layer, may be spaced apart from the pad portion PDP and the line portion LP.

In an embodiment, as described above, the pad portion PDP including the conductive pads CP may be formed in the second layer SL including or made of copper, and the line portion LP including the circuit lines CIL may be formed in the second layer SL, such that the second layer SL is electrically connected to each of the flexible circuit board FPCB and the part PRT. In such an embodiment, the pad portion PDP formed in the second layer SL of the cover panel CVP may be directly connected to the flexible circuit board FPCB to be electrically connected to the flexible circuit board FPCB, and the part PRT mounted on the first layer FL of the cover panel CVP may be electrically connected to the line portion LP of the second layer SL.

Accordingly, in an embodiment, an electronic part including a controller, a power supply, or the like is mounted in a way such that a separate printed circuit board capable of being connected to the flexible circuit board FPCB can be omitted. In such an embodiment, the total thickness and total weight of the display device DD is decreased as compared with a conventional display device including a printed circuit board, such that the display device DD can become thin in thickness and become light in weight. Also, in an embodiment, a process of attaching a printed circuit board to the flexible circuit board FPCB is omitted, such that manufacturing process can be simplified.

Hereinafter, an embodiment of a method of forming the pad portion PDP and the line portion LP in the second layer SL will be described.

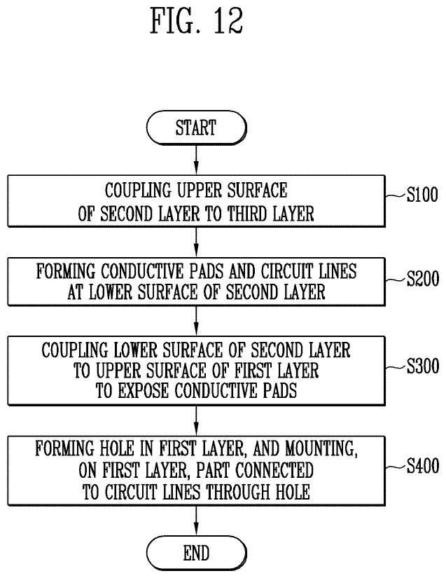

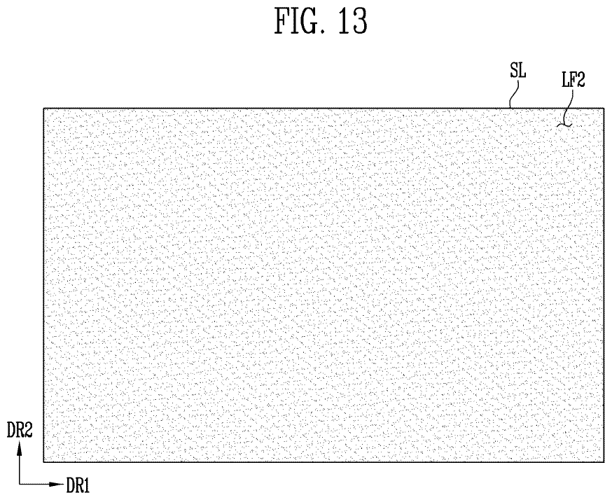

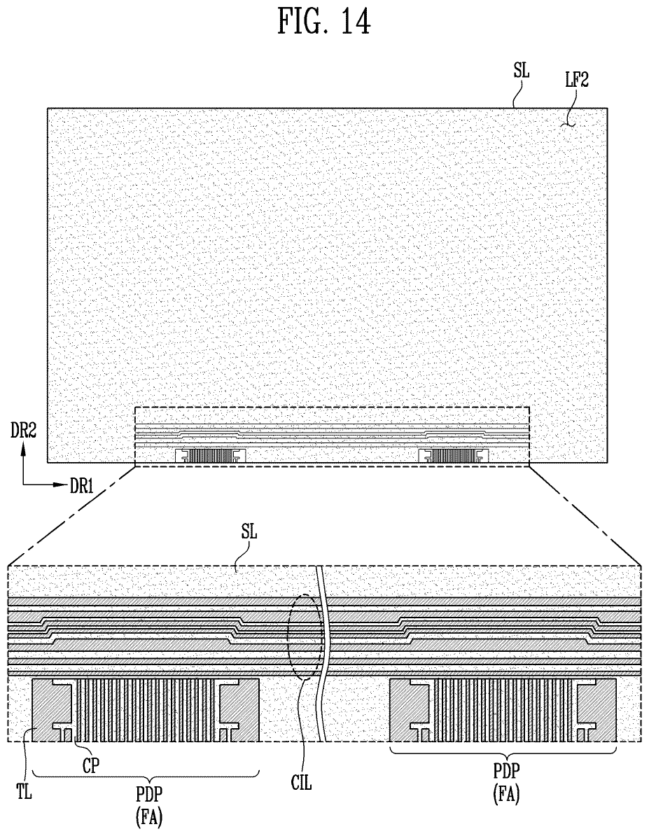

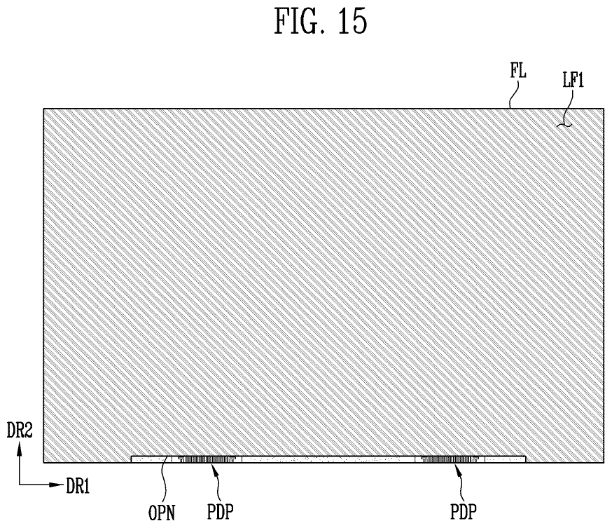

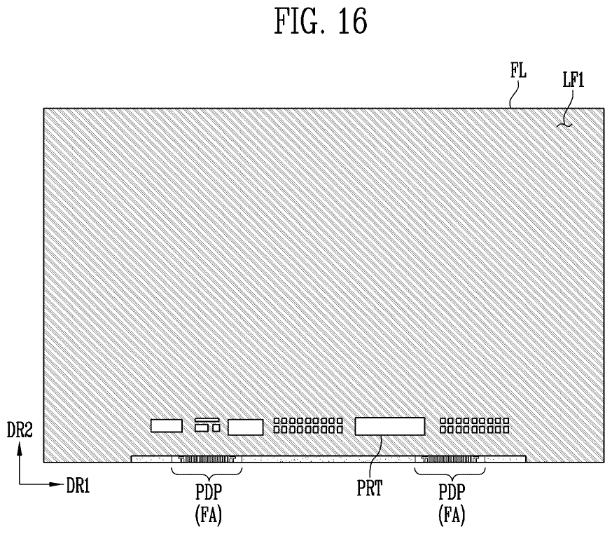

FIG. 12 is a schematic flowchart illustrating an embodiment of a method of manufacturing the cover panel CVP shown in FIG. 9. FIGS. 13 to 17 are schematic plan views illustrating processes of the method of manufacturing the cover panel CVP shown in FIG. 9.

In embodiments, processes of manufacturing the cover panel CVP shown in FIGS. 12 to 17 may be sequentially performed, some processes illustrated as being successively performed may be simultaneously performed, the sequence of the steps may be changed, some processes may be omitted, or another step may be further included between the processes without departing from the teachings herein.

In description of FIGS. 12 to 17, for convenience of description, any repetitive detailed descriptions of the same or like elements as those described above will be omitted. In FIGS. 12 to 17, for convenience, the lower surface (see “LF” shown in FIG. 7) of the cover panel (see “CVP” shown in FIG. 9) will be mainly described.

Referring to FIGS. 9, 12, and 13, in an embodiment of a method of manufacturing the cover panel CVP, an upper surface (see “UF2” shown in FIG. 9) of a second layer SL and a third layer (see “TL” shown in FIG. 9) are coupled to each other (S100).

The second layer SL may be a conductive layer including copper.

Referring to FIGS. 9 and 12 to 14, conductive pads CP and circuit lines CIL are formed at a lower surface LF2 of the second layer SL (S200).

The conductive pads CP and the circuit lines CIL may be formed through a process of removing a portion of the second layer SL, e.g., an etching process or the like. The conductive pads CP may constitute a pad portion PDP, and the circuit lines CIL may constitute a line portion LP. The pad portion PDP may be located in a first area FA of the second layer SL, and the line portion LP may be located in a second area SA of the second layer SL.

The third layer TL located between adjacent conductive pad CP in the first area FA may be exposed. In addition, the third layer TL located between adjacent circuit lines CIL in the second area SA may be exposed.

Referring to FIGS. 9 and 12 to 15, a first layer FL is located on the lower surface LF2 of the second layer SL, thereby coupling the second layer SL and the first layer FL to each other (S300).

The second layer SL including the pad portion PDP and the line portion LP and the first layer FL may be coupled to each other through hot press forming of applying heat and pressure.

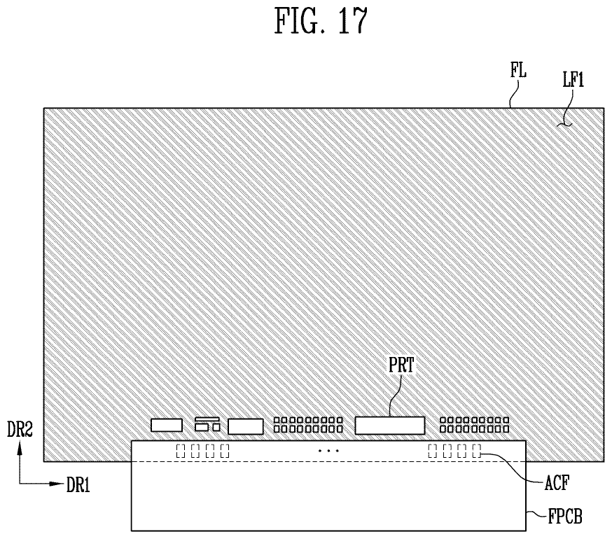

An opening portion OPN may be formed through the first layer FL to correspond to the pad portion PDP of the second layer SL. Conductive pads CP of the pad portion PDP may be exposed by the opening portion OPN of the first layer FL. The conductive pads CP exposed by the opening portion OPN may be connected to a flexible circuit board (see “FPCB” shown in FIG. 17) through a conductive adhesive layer (see “ACF” shown in FIG. 17) or the like. The conductive adhesive layer may include an anisotropic conductive film.

Referring to FIGS. 9 and 12 to 16, some of circuit lines CIL are exposed by forming a hole in the first layer FL, and a part PRT electrically connected to the circuit line CIL through the hole is mounted on the first layer FL (S400).

A process of forming the hole in the first layer FL may be performed using a drilling process or the like, but the disclosure is not limited thereto. The drilling process may be performed in an area of the first layer FL, which corresponds to the second area SA of the second layer SL, in which the circuit lines CIL are located.

The part PRT may be mounted directly on the area of the first layer FL to be electrically connected to the circuit lines CIL of the second layer SL through the hole formed through the drilling process. The area in which the part PRT is mounted in the first layer FL may correspond to the second area SA in which the line portion LP of the second layer SL is located.

After the part PRT is mounted on a lower surface LF1 of the first layer FL, the third layer TL may be coupled to a fourth layer (see “FOL” shown in FIG. 9), and the fourth layer FOL may be coupled to a fifth layer (see “FIL” shown in FIG. 9) to constitute the cover panel CVP. In some embodiments, a process of forming the fourth and fifth layers FOL and FIL on the third layer TL (or a process of coupling the third layer TL to the fourth and fifth layers FOL and FIL) may be performed before the part PRT is mounted on the lower surface LF1 of the first layer FL.

Also, after the part PRT is mounted, the flexible circuit board FPCB may be attached to one side of the cover panel CVP as shown in FIG. 17. In an embodiment, for example, the flexible circuit board FPCB may be bonded to the pad portion PDP of the cover panel CVP by the conductive adhesive layer ACF.

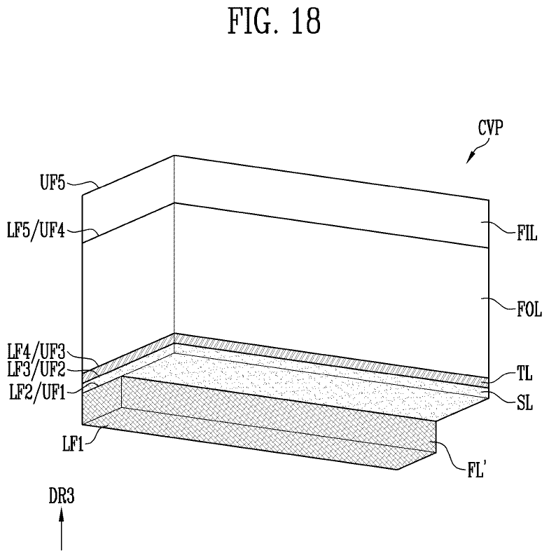

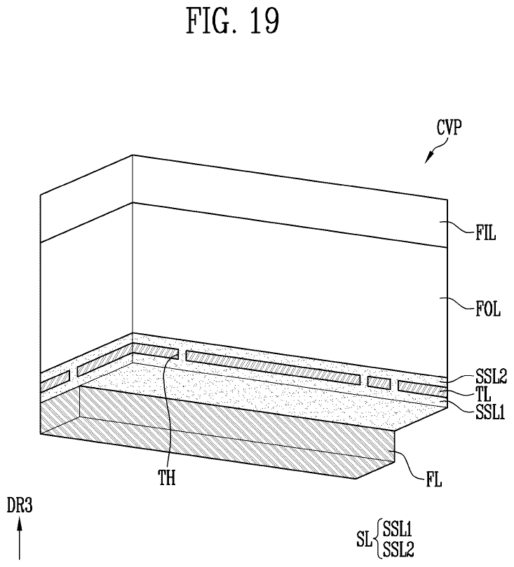

FIG. 18 and FIG. 19 are perspective views schematically illustrating a cover panel CVP in accordance with embodiments of the disclosure. In particular, FIG. 18 and FIG. 19 are schematic views illustrating a state in which the cover panel CVP is viewed from the bottom.

In description of the embodiments shown in FIG. 18 and FIG. 19, portions different from the portions of the above-described embodiment will be manly described to avoid redundancy.

In an embodiment, referring to FIG. 18, a cover panel CVP may include a first layer FL′, a second layer SL, a third layer TL, a fourth layer FOL, and a fifth layer FIL, which are sequentially stacked along the third direction DR3. The second layer SL may be located on the first layer FL′, the third layer TL may be located on the second layer SL, the fourth layer FOL may be located on the third layer TL, and the fifth layer FIL may be located on the fourth layer FOL.

The fifth layer FIL may be an embossed layer, the fourth layer FOL may be a cushion layer, the third layer TL may be a strength reinforcing layer, and the second layer SL may be a heat dissipation layer.

In an embodiment, the first layer FL′ may be a solder resist layer. The first layer FL′ may include a thermosetting resin or the like. The thermosetting resin may include, for example, epoxy resin, polyimide resin, Bismaleimide Triazine (BT) resin, Teflon resin, or the like. In an embodiment, for example, the first layer FL′ may be a prepreg obtained by impregnating the thermosetting resin into a reinforcement base, such as glass fabric or nonwoven glass fabric, to increase mechanical strength or resistance against temperature. The first layer FL′ may be formed through stacking by means of heating and pressurization.

The first layer FL′ may be located between the second layer SL and a part (see “PRT” shown in FIG. 7). In case that the first layer FL′ is provided as the solder resist layer, the first layer FL′ may have a thickness of about 20 μm in the third direction DR3 or a thickness of about 25 μm in the third direction DR3. In case that the first layer FL′ has a thickness of about 20 μm in the third direction DR3, the second layer SL may have a thickness of about 24.5 μm. Also, in case that the first layer FL′ has a thickness of about 25 μm in the third direction DR3, the second layer SL may have a thickness of about 19.5 μm.

When the material constituting the first layer FL′ is changed, the thickness of the second layer SL located on the first layer FL′ may be changed, but the disclosure is not limited thereto.

In another embodiment, referring to FIG. 19, a cover panel CVP may include a first layer FL, a second layer SL, a third layer TL, a fourth layer FOL, and a fifth layer FIL, which are sequentially stacked along the third direction DR3.

The fifth layer FIL may be an embossed layer, the fourth layer FOL may be a cushion layer, the third layer TL may be a strength reinforcing layer, the second layer SL may be a heat dissipation layer, and the first layer FL may be a protective layer.

The second layer SL may include a first sub-layer SSL1 and a second sub-layer SSL2. The first sub-layer SSL1 may be located between the first layer FL and the third layer TL, and the second sub-layer SSL2 may be located between the third layer TL and the fourth layer FOL. The first sub-layer SSL1 and the second sub-layer SSL2 may include or be made of a same conductive material. In an embodiment, for example, the first sub-layer SSL1 and the second sub-layer SSL2 may include or be made of copper.

The first sub-layer SSL1 and the second sub-layer SSL2 may face each other in the third direction DR3 while the third layer TL is interposed between the first sub-layer SSL1 and the second sub-layer SSL2. The pad portion PDP and/or the line portion LP, described with reference to FIG. 10 and FIG. 11, may be formed at a lower surface of the first sub-layer SSL1. The pad portion PDP and/or the line portion LP may also be formed at a lower surface of the second sub-layer SSL1. The first sub-layer SSL1 and the second sub-layer SSL2 may be electrically connected to each other through a penetration hole TH defined or formed through the third layer TL. The second layer SL may be implemented in a double-layer structure thanks to the first sub-layer SSL1 and the second sub-layer SSL2, which are electrically connected to each other. Accordingly, the heat dissipation performance of the second layer SL can be further improved.

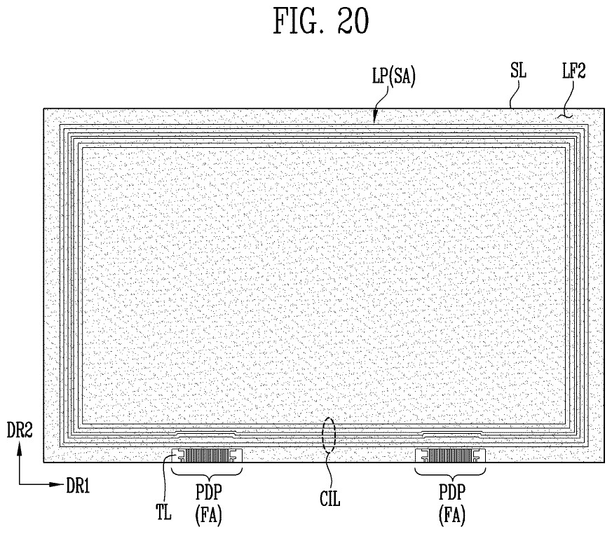

FIG. 20 is a schematic plan view illustrating the lower surface LF2 of the second layer SL of the cover panel shown in FIG. 9.

In description of the embodiment shown in FIG. 20, portions different from the portions of the above-described embodiment will be manly described to avoid redundancy.

Referring to FIGS. 9 and 20, in an embodiment, a pad portion PDP and a line portion LP may be formed in the second layer SL. The pad portion PDP may be located in the first area FA of the second layer SL, and the line portion LP may be located in the second area SA of the second layer SL.

The pad portion PDP may include a plurality of conductive patterns (see “CP” shown in FIG. 10). The pad portion PDP may be electrically connected to the flexible circuit board (see “FPCB” shown in FIG. 17) through the conductive adhesive layer (see “ACF” shown in FIG. 17).

The line portion LP may include a plurality of circuit lines CIL. The line portion LP may be electrically connected to the part (see “PRT” shown in FIG. 17) mounted on the lower surface (see “LF1” shown in FIG. 9) of the first layer (see “FL” shown in FIG. 9). In an embodiment, the circuit lines CIL may be arranged along an edge of the second layer SL. In an embodiment, for example, the circuit lines CIL may be arranged along an upper end portion, a lower end portion, a left end portion, and a right end portion of the second layer SL. The circuit lines CIL may be arranged to be spaced apart from the upper end portion, the lower end portion, the left end portion, and the right end portion of the second layer SL. Also, the circuit lines CIL may be arranged to be spaced apart from the pad portion PDP. As described above, in case that the circuit lines CIL are arranged along the edge of the second layer SL, an area of the second layer SL, in which the circuit lines CIL are not arranged, is not biased toward one side but may have a constant shape. Accordingly, the second layer SL can have uniform heat dissipation performance for each area.

In an embodiment where the circuit lines CIL are arranged along the edge of the second line SL, the part PRT including a control module and the like may be mounted on the first layer FL to correspond to the second area SA of the second layer SL, in which the circuit lines CIL are formed.

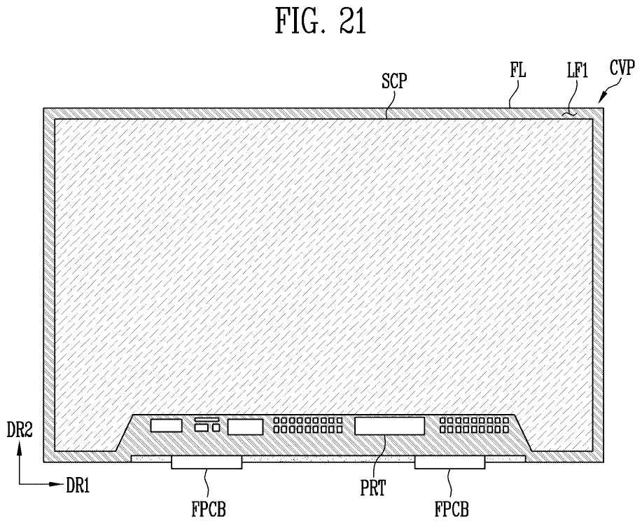

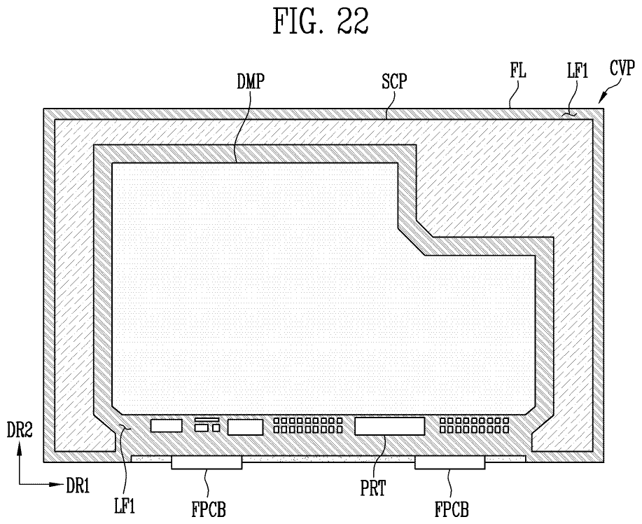

FIGS. 21 and 22 are plan views schematically illustrating a lower surface of the cover panel CVP in accordance with embodiments of the disclosure.

In description of the embodiments shown in FIG. 21 and FIG. 22, portions different from the portions of the above-described embodiment will be manly described to avoid redundancy.

Referring to FIG. 21 and FIG. 22, in an embodiment, a flexible circuit board FPCB may be attached to an end of the cover panel CVP. A part PRT may be mounted on the lower surface of the cover panel CVP (or the lower surface LF1 of the first layer FL).

The cover panel CVP may further include a step difference compensation pattern SCP located on the lower surface LF1 of the first layer FL. The step difference compensation pattern SCP may be a double-sided tape or an insulating film, but the disclosure is not limited thereto. The step difference compensation pattern SCP may compensate for a step difference occurring (or a stepped structured formed) due to components included in the part PRT.

The step difference compensation pattern SCP may be located on the lower surface LF1 of the first layer FL to be spaced apart from the part PRT.

In some embodiments, the cover panel CVP may further include a dummy pattern DMP located on the lower surface LF1 of the first layer FL. The dummy pattern DMP may be located on the lower surface LF1 of the first layer FL such that the step difference compensation pattern SCP and the part PRT are spaced apart from each other. The dummy pattern DMP may maintain a distance between the cover panel CVP (or the display module (see “DM” shown in FIG. 2)) and the accommodating container (see “BC” shown in FIG. 2). The dummy pattern DMP may absorb impact applied to the display device (see “DD” shown in FIG. 2). The dummy pattern DMP may include a material suitable for a design condition of the display device DD among materials having elasticity or materials capable of performing a supporting function. In some embodiments, the dummy pattern DMP may include a material suitable for additionally performing a heat dissipation function of discharging heat generated in the part PRT.

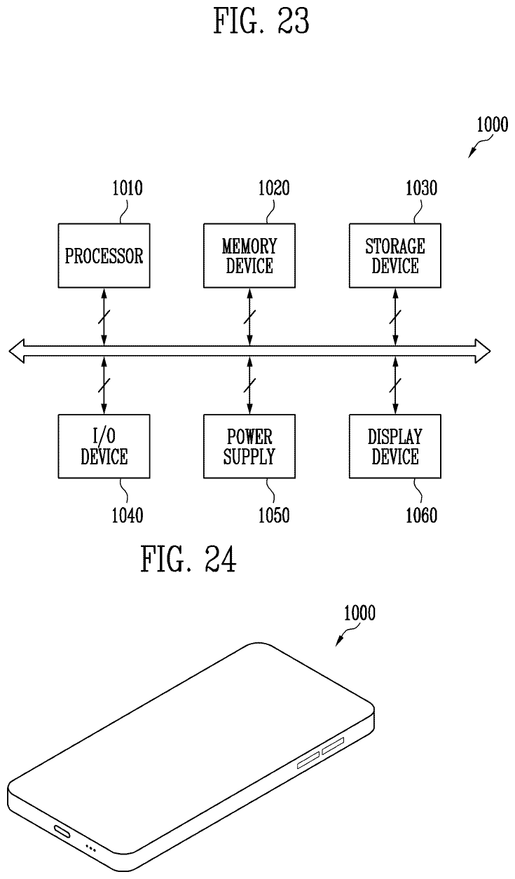

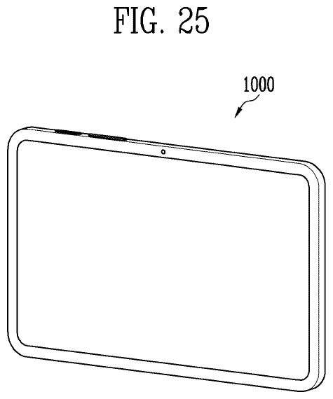

FIG. 23 is a schematic block diagram illustrating an electrode device 1000 in accordance with embodiments of the disclosure. FIG. 24 is a schematic view illustrating an embodiment in which the electronic device 1000 shown in FIG. 23 is implemented as a smartphone. FIG. 25 is a schematic view illustrating an embodiment in which the electronic device 1000 shown in FIG. 23 is implemented as a tablet PC.

Referring to FIGS. 23 to 25, an embodiment of the electronic device 1000 may include a processor 1010, a memory device 1020, a storage device 1030, an input/output (I/O) device 1040, a power supply 1050, and a display device 1060. The display device 1060 may correspond to the display device DD shown in FIGS. 1 and 2. Also, the electronic device 1000 may further include several ports capable of communicating with a video card, a sound card, a memory card, a USB device, and the like, or communicating with other systems. In an embodiment, as shown in FIG. 24, the electronic device 1000 may be implemented as a smartphone. In another embodiment, as shown in FIG. 25, the electronic device 1000 may be implemented as a tablet PC. However, this is merely illustrative, and the electronic device 1000 is not limited thereto. In an embodiment, for example, the electronic device 1000 may be implemented as a mobile phone, a video phone, a smart pad, a smart watch, a vehicle navigation system, a computer monitor, a notebook computer, a head mounted display device, or the like.

The processor 1010 may perform specific calculations or tasks. In some embodiments, the processor 1010 may be a microprocessor, a central processing unit, an application processor, or the like. The processor 1010 may be connected to other components through an address bus, a control bus, a data bus, and the like. In some embodiments, the processor 1010 may be connected to an extension bus such as a peripheral component interconnect (PCI) bus.

The memory device 1020 may store data used for an operation of the electronic device 1000. In an embodiment, for example, the memory device 1020 may include a nonvolatile memory device such as an Erasable Programmable Read-Only Memory (EPROM) device, an Electrically Erasable Programmable Read-Only Memory (EEPROM) device, a flash memory device, a Phase Change Random Access Memory (PRAM) device, a Resistance Random Access Memory (RRAM) device, a Nano Floating Gate Memory (NFGM) device, a Polymer Random Access Memory (PoRAM) device, a Magnetic Random Access Memory (MRAM) device, or a Ferroelectric Random Access Memory (FRAM) device, and/or a volatile memory device such as a Dynamic Random Access Memory (DRAM) device, a Static Random Access Memory (SRAM) device, or a mobile DRAM device.

The storage device 1030 may include a Solid State Drive (SSD), a Hard Disk Drive (HDD), a Compact Disc Read Only Memory (CD-ROM), and the like.

The I/O device 1040 may include an input means such as a keyboard, a keypad, a touch screen, or a mouse, and an output means such as a speaker or a printer. In some embodiments, the display device 1060 may be included in the I/O device 1040.

The power supply 1050 may supply power used for an operation of the electronic device 1000. In an embodiment, for example, the power supply 1050 may be a power management integrated circuit (PMIC).

The display device 1060 may display an image corresponding to visual information of the electronic device 1000. The display device 1060 may be an organic light emitting display device or a quantum dot light emitting display device, but the present disclosure is not limited thereto. The display device 1060 may be connected to other components through the buses or another communication link.

In accordance with the embodiments of the disclosure, a pad portion (or conductive pads) and a line portion (or circuit lines) are formed in a heat dissipation layer of a cover panel, the pad portion and a flexible circuit board are connected to each other, and a part and the line portion are electrically connected by mounting the part on a cover layer on the heat dissipation layer, such that a separate printed circuit board typically attached to a side of the flexible circuit board is omitted. Accordingly, the display device may further become thin in thickness and become light in weight.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display module which displays an image; and
an accommodating container which accommodates the display module therein,
wherein the display module includes:
a display panel;
a cover panel located on a lower surface of the display panel;
a flexible circuit board connected to the display panel and the cover panel; and
a part located on a lower surface of the cover panel,
wherein the cover panel includes a first layer disposed opposite to the display panel, a second layer disposed on the first layer, a third layer disposed on the second layer, a fourth layer disposed on the third layer, and a fifth layer disposed on the fourth layer, and
wherein the second layer includes a pad portion connected to the flexible circuit board and a line portion which is spaced apart from the pad portion and is connected to the part.

2. The display device of claim 1, wherein the pad portion includes a plurality of conductive pads, and the line portion includes a plurality of circuit lines, and
wherein the conductive pads and the circuit lines each includes copper.

3. The display device of claim 2, wherein the first layer defines an opening exposing the pad portion, and covers the circuit lines.

4. The display device of claim 3, wherein the part is disposed directly on a lower surface of the first layer which covers the circuit lines.

5. The display device of claim 3, wherein the third layer is disposed between the conductive pads, and
wherein the third layer is exposed by the opening of the first layer.

6. The display device of claim 2, wherein the first layer is a protective layer, the second layer is a heat dissipation layer, the third layer is a strength reinforcing layer, the fourth layer is a cushion layer, and the fifth layer is an embossed layer.

7. The display device of claim 6, wherein each of the first layer and the third layer includes polyimide and an adhesive layer.

8. The display device of claim 1, wherein the second layer includes a first sub-layer and a second sub-layer, and
wherein the first sub-player is disposed between the first layer and the third layer, and the second sub-layer is disposed between the third layer and the fourth layer.

9. The display device of claim 8, wherein the first sub-layer and the second sub-layer correspond to a heat dissipation layer including copper.

10. The display device of claim 9, wherein the first sub-layer and the second sub-layer are electrically connected to each other through a penetration hole defined through a portion of the third layer.

11. The display device of claim 2, wherein the first layer is a solder resist layer, the second layer is a heat dissipation layer, the third layer is a strength reinforcing layer, the fourth layer is a cushion layer, and the fifth layer is an embossed layer.

12. The display device of claim 1, wherein the cover panel further includes a step difference compensation pattern disposed on a lower surface of the first layer, and
wherein the step difference compensation pattern is disposed on the lower surface of the first layer to be spaced apart from the part.

13. The display device of claim 12, wherein the cover panel further includes a dummy pattern disposed on the lower surface of the first layer, and
wherein the dummy pattern is spaced apart from the step difference compensation pattern and the part.

14. The display device of claim 13, wherein the dummy pattern maintains a distance between the display module and the accommodating container.

15. The display device of claim 2, wherein the circuit lines are arranged along an edge of the second layer.

16. The display device of claim 1, wherein the display panel includes:
a substrate;
a pixel circuit layer disposed on the substrate, wherein the pixel circuit layer includes a transistor; and
a display element layer disposed on the pixel circuit layer, wherein the display element layer includes a light emitting element which emits light.

17. An electronic device comprising:
a processor which provides input image data to a display device; and
the display device which displays an image, based on the input image data,
wherein the display device includes:
a display panel;
a cover panel disposed on a lower surface of the display panel;
a flexible circuit board connected to each of the display panel and the cover panel; and
a part located on a lower surface of the cover panel,
wherein the cover panel includes a protective layer, a heat dissipation layer, a strength reinforcing layer, a cushion layer, and an embossed layer, which are sequentially stacked in a direction opposite to the display panel,
wherein the heat dissipation layer includes copper, and
wherein the heat dissipation layer includes a pad portion connected to the flexible circuit board and a line portion which is spaced apart from the pad portion and is connected to the part.

18. The electronic device of claim 17, wherein the heat dissipation layer includes a first area, in which the pad portion is disposed, and a second area, in which the line portion is disposed, and
wherein the pad portion includes a plurality of conductive pads, and the line portion includes a plurality of circuit lines.

19. The electronic device of claim 18, wherein the protective layer and the strength reinforcing layer include polyimide, and
wherein the protective layer defines an opening exposing the first area, and covers the line portion.

20. The electronic device of claim 18, wherein the part is disposed directly on a low surface of the protective layer which covers the circuit lines.
